(19) United States
(12) Patent Application Publication
(10) Pub. No.: US 2025/0300614 A1
(43) Pub. Date: Sep. 25, 2025

(54) AMPLIFIER

(71) Applicant: ABLIC Inc., Nagano (JP)

(72) Inventor: Yuji SHIINE, Nagano (JP)

(73) Assignee: ABLIC Inc., Nagano (JP)

(21) Appl. No.: 19/070,487

(22) Filed: Mar. 4, 2025

(30) Foreign Application Priority Data
Mar. 19, 2024 (JP) 2024-043429

(51) Int. Cl. H03F 3/393; H03F 1/32

(52) U.S. Cl. CPC H03F 3/393; H03F 1/3211; H03F 2200/271; H03F 2200/333

(57) ABSTRACT

An amplifier includes: a signal polarity inversion circuit; an amplifier circuit, connected with the signal polarity inversion circuit, generating a current based on a voltage, and outputting the current from output terminals; a signal polarity inversion circuit, having input terminals respectively connected with the output terminals, and outputting, in a non-inverted or inverted polarity, the current output from the amplifier circuit; a capacitor, obtaining a voltage based on the current output from the signal polarity inversion circuit; and a compensation circuit, wherein a node 12 and a node 10 are connected and a node 13 and a node 11 are connected, an input error component current comprising an input error component of the amplifier circuit is extracted from a voltage between terminals of the capacitor, and the input error component current that is extracted is supplied to the node 10 and the node 11.

### CROSS-REFERENCE TO RELATED APPLICATION

This application claims the priority benefit of Japan application serial no. 2024-043429, filed on Mar. 19, 2024. The entirety of the above-mentioned patent application is hereby incorporated by reference herein and made a part of this specification.

### BACKGROUND

### Technical Field

The invention relates to an amplifier.

### Description of Related Art

A chopper amplifier is known as an amplifier for amplifying small signals. A conventional chopper amplifier includes a chopper modulator, a first-stage differential amplifier, a chopper demodulator, a second-stage differential amplifier, and a filter disposed in the signal path from the input terminal to the output terminal (for example, see Japanese Patent Application Laid-Open Publication No. 2014-216705).

However, in the conventional chopper amplifier, the resistance and capacitance tend to increase in order to enhance the attenuation effect of the filter disposed in the signal path. In other words, the area occupied by the filter is large, leading to an increase in chip area. Additionally, the signal component output from the output terminal is a signal component after passing through the filter disposed in the signal path. Thus, the signal component is affected by the distortion caused by the filter. In other words, in the conventional chopper amplifier, the amplification accuracy deteriorates due to the influence of the filter, resulting in a decrease in signal quality.

The invention provides an amplifier capable of outputting a signal component free from the influence of distortion caused by the filter, without reducing the accuracy of removing error components included in the input signal.

### SUMMARY

An amplifier according to an aspect of the invention includes: a first signal polarity inversion circuit, outputting, in a non-inverted or inverted polarity, an input signal input from an input terminal; a first voltage-current conversion circuit, connected with the first signal polarity inversion circuit, generating an output current based on an output voltage of the first signal polarity inversion circuit, and outputting the output current from a first output terminal and a second output terminal; a second signal polarity inversion circuit, having a first input terminal and a second input terminal respectively connected with the first output terminal and the second output terminal of the first voltage-current conversion circuit, and outputting, in a non-inverted or inverted polarity, the current output from the first voltage-current conversion circuit; a load capacitor, connected with the second signal polarity inversion circuit, and obtaining a voltage based on the current output from the second signal polarity inversion circuit; and a compensation circuit, wherein a first terminal of the load capacitor and a first node are connected, the first node being a connection point between the first output terminal of the first voltage-current conversion circuit and a first input terminal of the second signal polarity inversion circuit, a second terminal of the load capacitor and a second node are connected, the second node being a connection point between the second output terminal of the first voltage-current conversion circuit and a second input terminal of the second signal polarity inversion circuit, a voltage between the terminals of the load capacitor includes an input error component of the first voltage-current conversion circuit, and an input error component current corresponding to the input error component is extracted from the voltage between the terminals of the load capacitor, the input error component current that is extracted is negatively fed back to the first node and the second node.

### BRIEF DESCRIPTION OF THE DRAWINGS

FIG. 1 is a block diagram illustrating a configuration example of an amplifier according to an embodiment of the invention.

FIG. 2 is a circuit diagram illustrating a configuration example of a signal polarity inversion circuit in the amplifier according to the embodiment.

FIG. 3 is a circuit diagram illustrating a configuration example of a sample hold integrator circuit in the amplifier according to the embodiment.

FIG. 4 is a time chart illustrating the operation of the amplifier according to the embodiment.

FIG. 5 is a time chart of the sample hold integrator circuit in the amplifier according to the embodiment.

### DESCRIPTION OF THE EMBODIMENTS

According to the invention, it is possible to obtain a signal component that is not affected by the distortion caused by the filter, without reducing the accuracy of removing error components included in the input signal.

The following describes an amplifier according to an embodiment of the present invention with reference to the drawings.

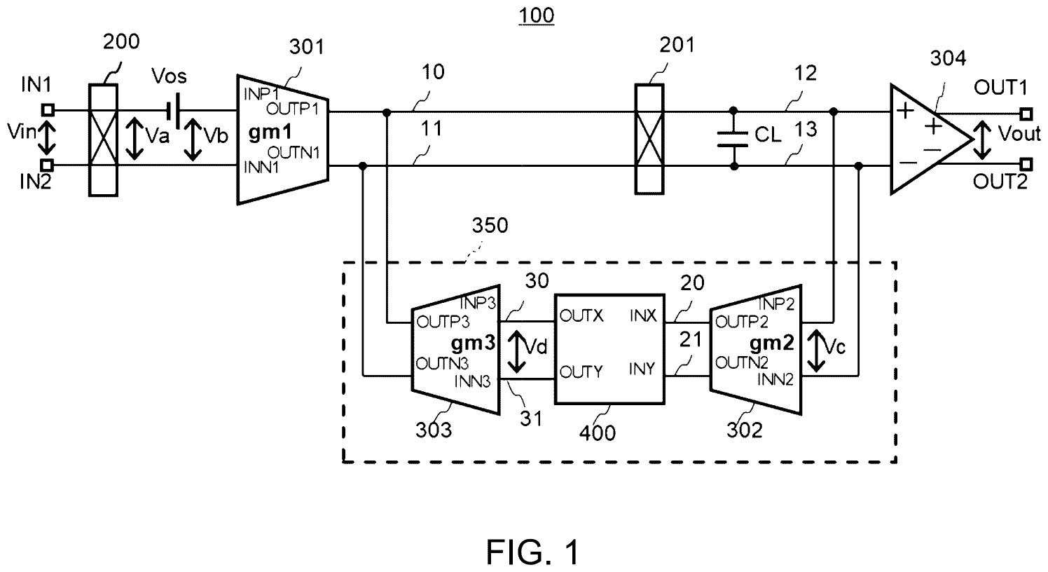

FIG. 1 is a block diagram of an amplifier 100 serving as an example of an amplifier according to an embodiment of the invention.

The amplifier 100 includes a signal polarity inversion circuit 200 for modulation, a first-stage amplifier circuit 301, a signal polarity inversion circuit 201 for demodulation, a second-stage amplifier circuit 304, an OTA 302, a sample hold integrator circuit 400 having a signal component separation function, an OTA 303, input terminals IN1 and IN2, and output terminals OUT1 and OUT2. The OTA 302, the sample hold integrator circuit 400, and the OTA 303 form a compensation circuit 350 configured to compensate for the input error current included in the output signal from the amplifier circuit 301.

The amplifier circuit 301 is formed by an operational transconductance amplifier (OTA) with a transconductance gm1, the OTA including input terminals INP1 and INN1, and output terminals OUTP1 and OUTN1, the OTA serving as the voltage-current conversion circuit. The amplifier circuit 301 has an input offset voltage. As an example, an offset voltage Vos is illustrated at the input terminal INP1.

The OTA 302 is an operational transconductance amplifier (OTA) with a transconductance gm2, having input terminals INP2 and INN2, and output terminals OUTP2 and OUTN2. The OTA 303 is an operational transconductance amplifier with a transconductance gm3, having input terminals INP3 and INN3, and output terminals OUTP3 and OUTN3. The amplifier circuit 304 is formed by a fully differential amplifier circuit. The OTA 302 and 303 also serve as the voltage-current conversion circuit.

The compensation circuit 350 is a negative feedback circuit which connects from nodes 12 and 13 to nodes 10 and 11, and feeds back a current based on a voltage Vc between the nodes 12 and 13. Here, the nodes 12 and 13 are the connection points between the signal polarity inversion circuit 201 and the amplifier circuit 304, and respectively correspond to a first and a second input nodes of the compensation circuit 350. The nodes 10 and 11 are the connection points between the amplifier circuit 301 and the signal polarity inversion circuit 200, respectively correspond to a first and a second output nodes of the compensation circuit 350.

In the OTA 302, the input terminal INP2 is connected to the node 12, and the input terminal INN2 is connected to the node 13. The output terminal OUTP2 is connected to an input terminal INX of the sample hold integrator circuit 400, and the output terminal OUTN2 is connected to an input terminal INY of the sample hold integrator circuit 400. A connection point between the output terminal OUTP2 and the input terminal INX forms a node 20, and a connection point between the output terminal OUTN2 and the input terminal INY forms a node 21.

In the OTA 303, the input terminal INP3 is connected to an output terminal OUTX of the sample hold integrator circuit 400 and forms a node 30. Additionally, the input terminal INN3 is connected to an output terminal OUTY of the sample hold integrator circuit 400 and forms a node 31. Furthermore, the output terminal OUTP3 is connected to a node 10, and the output terminal OUTN3 is connected to a node 11.

In the amplifier 100, an input signal Vin input between the input terminals IN1 and IN2 is modulated by the signal polarity inversion circuit 200, and a modulated signal of a voltage Va is output. The modulated signal is supplied to the amplifier circuit 301 having an offset voltage Vos, and a voltage Vb including the offset voltage Vos is converted to current and output. Here, in the amplifier circuit 301, in the case where the difference between the voltage of the input terminal INP1 and the voltage of the input terminal INN1, i.e., the voltage Vb, is positive (Vb>0), the larger the difference, the larger the current sourced from the output terminal OUTP1 and sunk from the output terminal OUTN1. Meanwhile, in the case where the voltage Vb is negative (Vb<0), the larger the difference, the larger the current is sunk from the output terminal OUTP1 and sourced from the output terminal OUTN1.

The current output from the amplifier circuit 301 includes an input error component. The current output from the amplifier circuit 301 is demodulated by the signal polarity inversion circuit 201, and the voltage Vc of two ends of the capacitor CL connected between node 12 and node 13 is supplied to both the amplifier circuit 304 and the compensation circuit 350, the capacitor CL serving as the load capacitor.

The voltage supplied to the amplifier circuit 304 is amplified by the amplifier circuit 304, and then output as an output voltage Vout between the output terminals OUT1 and OUT2 connected to the amplifier circuit 304.

Meanwhile, the voltage Vc supplied to the compensation circuit 350 is converted into a current by the OTA 302, and then the charge is accumulated and redistributed by the sample hold integrator circuit 400. The input error component current of the amplifier circuit 301 is extracted by the OTA 303, and the input error component current included in the current output from the amplifier circuit 301 is canceled.

Here, the OTA 302 and the OTA 303 possess voltage-current conversion characteristics similar to those of the amplifier circuit 301. That is, in the OTA 302 and the OTA 303, when the voltage Vc, which is the difference between the voltage at the input terminal INP2 and the voltage at the input terminal INN2, and the voltage Vd, which is the difference between the voltage at the input terminal INP3 and the voltage at the input terminal INN3, are positive (Vc>0, Vd>0), the larger the difference, the larger the currents are sourced from the output terminals OUTP2 and OUTP3 and sunk from the output terminals OUTN2 and OUTN3, respectively.

Meanwhile, in the case where the voltage Vc and the voltage Vd are negative (Vb<0), the larger the difference, the larger the currents are sunk from the output terminals OUTP2 and OUTP3 and sourced from the output terminals OUTN2 and OUTN3, respectively.

The following describes in more detail the configuration of the signal polarity inversion circuits 200, 201 and the sample hold integrator circuit 400.

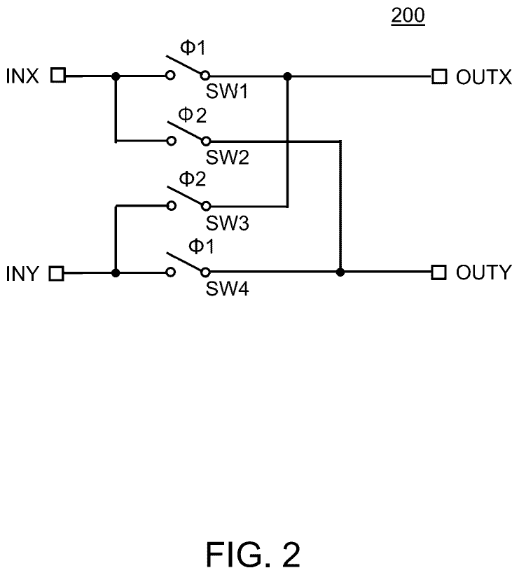

FIG. 2 is a circuit diagram illustrating a configuration example of the signal polarity inversion circuit 200. Since the signal polarity inversion circuit 201 does not substantially differ from the signal polarity inversion circuit 200, the description of the signal polarity inversion circuit 201 is omitted given the description of the signal polarity inversion circuit 200. In other words, by reinterpreting the reference symbol from 200 to 201, the description of the signal polarity inversion circuit 200 can be replaced by the description of the signal polarity inversion circuit 200.

The signal polarity inversion circuit 200 includes an input terminal INX, an input terminal INY, four switches SW1, SW2, SW3, SW4, an output terminal OUTX, and an output terminal OUTY. The input terminal INX is connected to the input terminal IN1 (FIG. 1), while the input terminal INY is connected to the input terminal IN2 (FIG. 1). The output terminal OUTX is connected to the input terminal INP1 (FIG. 1) of the amplifier circuit 301, while the output terminal OUTY is connected to the input terminal INN1 (FIG. 1) of the amplifier circuit 301.

The input terminal INX is connected to the output terminal OUTX through the switch SW1, and is also connected to the output terminal OUTY through the switch SW2. The input terminal INY is connected to the output terminal OUTX through the switch SW3, and is also connected to the output terminal OUTY through the switch SW4. The signal polarity inversion circuit 201 synchronizes with the control signals φ1 and φ2 and switches the polarity of the signals input to the input terminals INX and INY to become either inverted or non-inverted, and outputs the signals to the output terminals OUTX and OUTY.

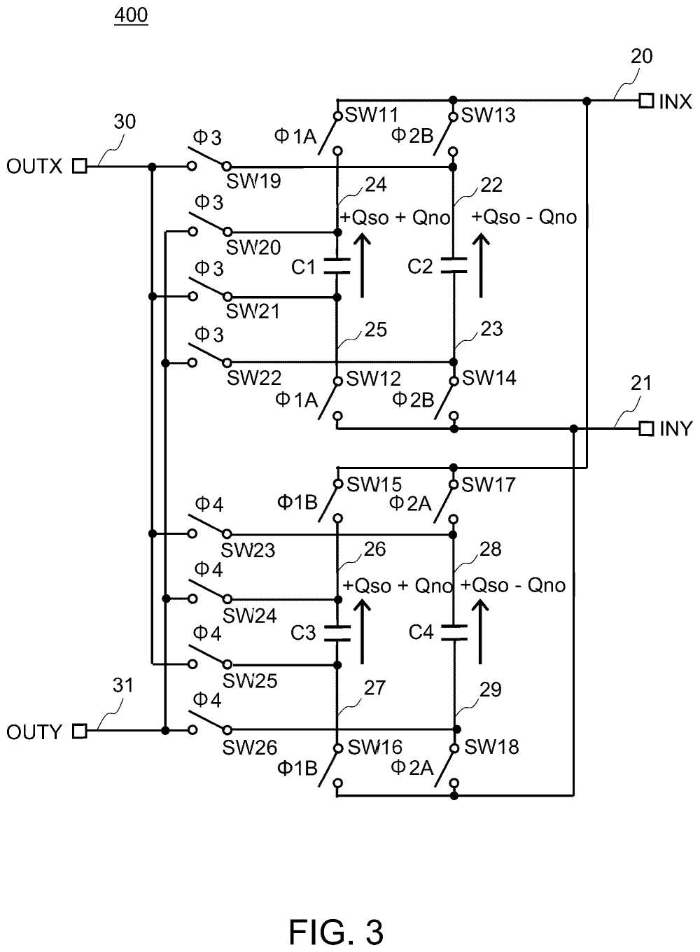

FIG. 3 is a circuit diagram illustrating a configuration example of the sample hold integrator circuit 400 having a signal component separation function.

The sample hold integrator circuit 400 includes the input terminals INX and INY, the output terminals OUTX and OUTY, eight switches SW11, SW12, SW13, SW14, SW15, SW16, SW17, SW18, and sampling capacitors C1, C2, C3, C4.

In the sample hold integrator circuit 400, the input terminal INX is connected to the output terminal OUTP2, and is also connected to a first terminal of each of the capacitors C1, C2, C3, C4 through the switches SW11, SW13, SW15, SW17, respectively. The input terminal INY is connected to the output terminal OUTN2, and is also connected to a second terminal of each of the capacitors C1, C2, C3, C4 through the switches SW12, SW14, SW16, SW18, respectively. Here, a connection point between and the switch SW13 and the capacitor C2 will be referred to as “node 22”, a connection point between and the switch SW14 and the capacitor C2 will be referred to as “node 23”, a connection point between and the switch SW11 and the capacitor C1 will be referred to as “node 24”, a connection point between and the switch SW12 and the capacitor C1 will be referred to as “node 25”, a connection point between and the switch SW15 and the capacitor C3 will be referred to as “node 26”, a connection point between and the switch SW16 and the capacitor C3 will be referred to as “node 27”, a connection point between and the switch SW17 and the capacitor C4 will be referred to as “node 28”, a connection point between and the switch SW18 and the capacitor C4 will be referred to as “node 29”.

In the sample hold integrator circuit 400, the output terminal OUTX is connected to the first terminal of the capacitor C2 through the switch SW19, the second terminal of the capacitor C1 through the switch SW21, the first terminal of the capacitor C4 through the switch SW23, and the second terminal of the capacitor C3 through the switch SW25, respectively. The output terminal OUTY is connected to the first terminal of the capacitor C1 through the switch SW20, the second terminal of the capacitor C2 through the switch SW22, the first terminal of the capacitor C3 through the switch SW24, and the second terminal of the capacitor C4 through the switch SW26, respectively.

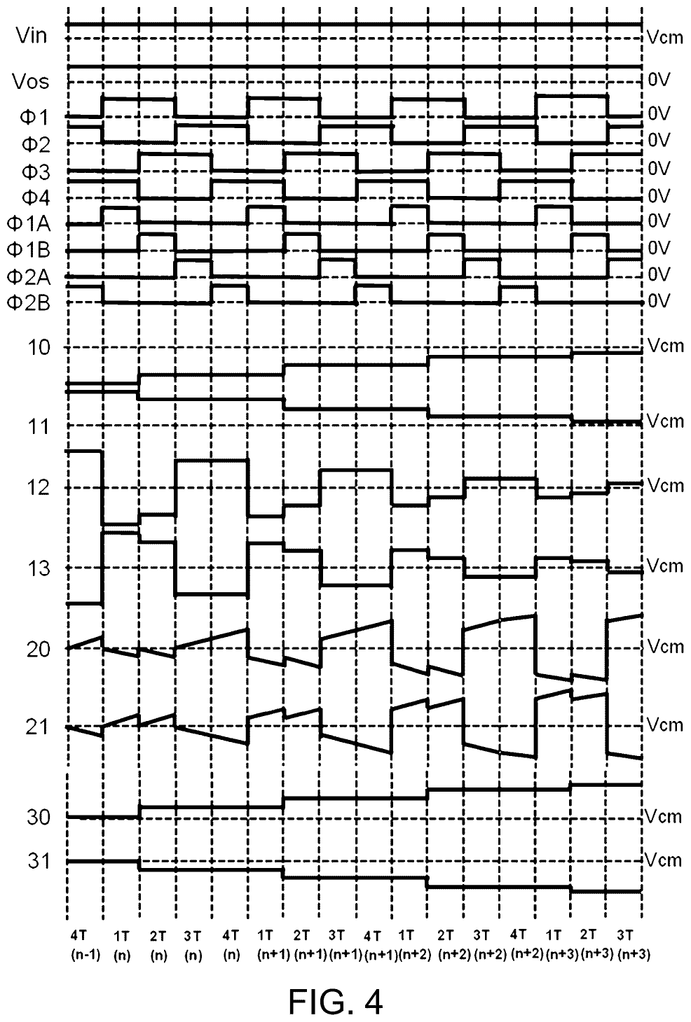

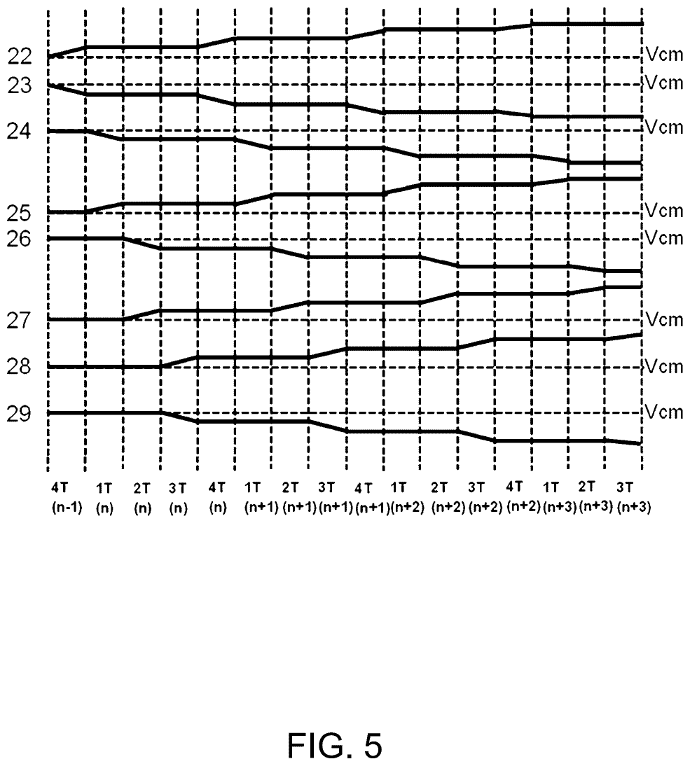

As described above, the amplifier 100 so configured is capable of enabling signal addition and subtraction in a capacitor by arranging the output signals of the amplifier circuit 301 and OTAs 302, 303 as currents, thus facilitating signal addition and subtraction without complicating the configuration. The amplifier 100, by being switch-controlled at the timing to be exemplified in FIG. 4 and FIG. 5, allows the compensation circuit 350 to remove only the signal component current from a current with a mixture of the signal component of the signal as an amplification target and the input error component of the amplifier circuit 301, thereby extracting only the input error component current of the amplifier circuit 301. The amplifier 100 cancels the input error component of the amplifier circuit 301 by gradually applying negative feedback through discrete analog operation to nodes 10 and 11, which are the output nodes of the amplifier circuit 301, by using the input error component current of the amplifier circuit 301 extracted by the compensation circuit 350.

The operation of the amplifier 100 will now be described.

FIG. 4 is a time chart illustrating the operation example of the amplifier 100, and FIG. 5 is a time chart of the sample hold integrator circuit 400. Here, each horizontal axis of the time charts illustrated in FIGS. 4 and 5 is an axis representing time, and each horizontal axis of both time charts represents same time zone. The vertical axis of the time chart illustrated in FIG. 4 represents each voltage of the input signal Vin, the offset voltage Vos, the control signals φ1, φ2, φ3, φ4, φ1A, φ1B, φ2A and φ2B, and the nodes 10 to 13, 20, 21, 30 and 31, respectively. The vertical axis of the time chart illustrated in FIG. 5 represents each voltage of the nodes 22 to 29 in the sample hold integrator circuit 400, respectively.

One cycle of the operation of the amplifier 100 includes the periods from 1T to 4T, with each period having the same length (ΔT). The input signal Vin has a frequency sufficiently lower than the frequencies of control signals φ1, φ2, etc., so the input signal Vin appears almost as a DC voltage in FIG. 4.

The control signal φ1 is at a high level (hereinafter referred to as “H level”) during the periods 1T to 2T, and at a low level (hereinafter referred to as “L level”) during the periods 3T to 4T. The control signal φ2 is at L level during the periods 1T to 2T, and at H level during the periods 3T to 4T. That is, the level of the control signal φ2 transitions at a timing that is opposite to that of the control signal φ1.

Thus, in the signal polarity inversion circuits 200, 201, during the periods 1T to 2T, the input terminal INX is connected to the output terminal OUTX, and the input terminal INY is connected to the output terminal OUTY. In the subsequent periods 3T to 4T, the input terminal INX is connected to the output terminal OUTY, and the input terminal INY is connected to the output terminal OUTX.

As the signal polarity inversion circuit 200 operates as described above, for the voltage Va between the output terminal OUTX and the output terminal OUTY of the signal polarity inversion circuit 200, the voltage value becomes +Vin during the periods 1T to 2T and −Vin during the periods 3T to 4T, centered around the operating point voltage Vcm of the input signal Vin. In other words, the signal polarity inversion circuit 200 serves as a modulator, and the voltage Va is the voltage of the modulation signal that appears between the output terminal OUTX and the output terminal OUTY.

The voltage Vb that appears between the input terminal INP1 and the input terminal INN1 of the amplifier circuit 301 becomes a voltage with the DC offset voltage Vos added to the voltage Va. Specifically, the voltage value becomes +Vos+Vin during the periods 1T to 2T and +Vos−Vin during the periods 3T to 4T.

Assuming the current output by the amplifier circuit 301 during the periods 1T to 2T as a current I11 and the current output during the periods 3T to 4T as a current I12, the currents I11 and I12 can be represented in Equations (1) and (2) as follows by using the transconductance gm1:

$$I 11 = gm 1 \times ( + Vos + Vin ) \qquad ( 1 )$$

$$I 12 = gm 1 \times ( + Vos - Vin ) \qquad ( 2 )$$

The currents I11 and I12 are input to the signal polarity inversion circuit 201.

The signal polarity inversion circuit 201 operates in the same manner as the signal polarity inversion circuit 200 as described above. Thus, chopper demodulation is performed on the signal component of the input signal Vin at a frequency fc, while chopper modulation is performed on the input error component of the amplifier circuit 301 at the frequency fc. The current flowing into the nodes 12 and 13, which are the output nodes of the signal polarity inversion circuit 201, becomes non-inverted (=I11) during the periods 1T to 2T and inverted (=−I12) during the periods 3T to 4T.

Here, assuming that the capacitance value of the capacitor CL connected between the node 12 and the node 13 as C, and the time for the periods 1T to 2T and the time for the periods 3T to 4T as 2ΔT, then the voltages Vc1 and Vc2 generated between the nodes 12 and 13 during the periods 1T to 2T of the voltage Vc generated between the nodes 12 and 13 can be expressed by Equations (3) and (4) as follows. The voltages Vc1 and Vc2 are input to the amplifier circuit 304 and the OTA 302, respectively.

$$\begin{matrix}[ Formula 1 ] & \\ Vc 1 = \frac{gm 1 \times ( + Vin + Vos )}{C} \times 2 Δ T & ( 3 )\end{matrix}$$

$$Vc 2 = \frac{gm 1 \times ( + Vin - Vos )}{C} \times 2 Δ T \qquad ( 4 )$$

The OTA 302 outputs currents proportional to the voltages Vc1 and Vc2. Of the currents output from the OTA 302, the currents Ic1 and Ic2 output from the OTA 302 during the periods 1T to 2T can be respectively expressed by Equations (5) and (6) in the following by using the transconductance gm2. The currents Ic1 and Ic2 output from the OTA 302 are input to the sample hold integrator circuit 400.

$$\begin{matrix}[ Formula 2 ] & \\ Ic 1 = \frac{gm 1 \times gm 2 \times ( + Vin + Vos )}{C} \times 2 Δ T \times 2 Δ T & ( 5 )\end{matrix}$$

$$Ic 2 = \frac{gm 1 \times gm 2 \times ( + Vin - Vos )}{C} \times 2 Δ T \times 2 Δ T \qquad ( 6 )$$

The sample hold integrator circuit 400 synchronizes with control signals φ1A, φ2A, φ1B, and φ2B to sample the current containing a mixture of the signal component output by the OTA 302 and the input error component of the amplifier circuit 301 in the capacitors C2 and C4 only during the periods 1T to 2T, which are the periods where the polarity of the input error component of the amplifier circuit 301 does not invert, and to sample to the capacitors C1 and C3 only during the periods 3T to 4T, which is the period where the polarity of the input error component of the amplifier circuit 301 inverts.

After the capacitors C2, C4 and the capacitors C1, C3 are charged separately, the capacitors C1 and C2 are connected via the switches SW19, SW20, SW21, SW22, and the capacitors C3 and C4 are connected via the switches SW23, SW24, SW25, SW26. Accordingly, by redistributing the charges charged to the capacitors C1, C2, C3, C4, only the signal component current is removed from the current in which the signal component and the input error component of the amplifier circuit 301 are mixed, and only the input error component current of the amplifier circuit 301 is extracted.

In addition, an integration function is provided by, during an analog discrete operation in which the operation of the periods 1T to 4T are set as one cycle, storing the magnitude of the input error component of the amplifier circuit 301 during the n^{th} operation period as a capacitor charging voltage, and starting the sampling of the input error component of the amplifier circuit 301 during the (n+1)^{th} analog discrete operation from the capacitor charging voltage of the n^{th} operation, n being a natural number.

Based on the current output from the OTA 302, the sample hold integrator circuit 400, for example, charges the capacitor C2 with a charge of gm1×gm2×(+Vin−Vos)×2ΔT÷C×ΔT through the switches SW13 and SW14 during the period 4T, and charges the capacitor C1 with a charge of gm1×gm2×(+Vin+Vos)×2ΔT÷C×ΔT through the switches SW11 and SW12 during the period 1T. Subsequently, during the periods 2T to 3T, the sample hold integrator circuit 400 connects the capacitors C1 and C2 through the switches SW19, SW20, SW21, SW22 to redistribute the charging charge. A charge Q12 remaining in the capacitors C1 and C2 after the redistribution of the charging charge can be expressed by Equation (7): −gm1×gm2×Vos×2ΔT÷C×ΔT×2.

$$\begin{matrix}[ Formula 3 ] & \\ Q 12 = - \frac{gm 1 \times gm 2 \times {V}_{OS}}{C} \times 2 Δ T \times Δ T \times 2 & ( 7 )\end{matrix}$$

As illustrated in Equation (5) above, by connecting the capacitor C1 and the capacitor C2 during the periods 2T to 3T and redistributing the charging charge, the signal component is removed, and only the charge of the input error component of the amplifier circuit 301, namely the offset voltage Vos, is extracted to the capacitor C1 and the capacitor C2 respectively. Moreover, since the charging charge Q(n) after charge redistribution during the periods 2T to 3T in the n^{th} operation period of the analog discrete operation where the periods 1T to 4T are set as one cycle is retained in the capacitor C1 and the capacitor C2, the charging to the capacitor C1 and the capacitor C2 in the (n+1)^{th} analog discrete operation starts with the retained charge Q(n) as the initial value. Thus, the sample hold integrator circuit 400 possesses integration properties.

Like the capacitors C1 and C2, for the capacitors C3 and C4, based on the current output from the OTA 302, for example, during the period 2T, a charge of gm1×gm2×(+Vin+Vos)×2ΔT÷C×ΔT is charged to the capacitor C3 through the switches SW15 and SW16, and during the period 3T, a charge of gm1×gm2×(+Vin−Vos)×2ΔT÷C×ΔT is charged to the capacitor C4 through the switches SW17 and SW18. Subsequently, during the period 4T to 1T, the capacitors C3 and C4 are connected through the switches SW23, SW24, SW25, SW26 to redistribute the charging charge.

A charge Q34 remaining in the capacitors C3 and C4 after the redistribution of the charging charge can be represented by Equation (7): −gm1×gm2×Vos×2ΔT−C×ΔT×2, where the signal component is removed, and only the charge of the offset voltage Vos corresponding to the input error component of the amplifier circuit 301 is charged. Moreover, since the charging charge Q(n) after charge redistribution during the periods 4T to 1T in the n^{th} operation period of the analog discrete operation, where the periods 1T to 4T constitute one cycle, is retained in the capacitor C3 and the capacitor C4, the charging to the capacitor C3 and the capacitor C4 in the (n+1)^{th} analog discrete operation starts with the retained charge Q(n) as the initial value. Thus, the sample hold integrator circuit 400 with signal component separation function possesses integration properties.

When the capacitance values of the capacitors C1, C2, C3, and C4 are set as Cs, the voltage Vd between the output terminal OUTX and the output terminal OUTY of the sample hold integrator circuit 400 during the periods 2T to 3T and 4T to 1T can be expressed by Equation (8): −gm1×gm2×Vos×2ΔT÷C×ΔT×2÷(Cs×2) and is input to the OTA303.

$$\begin{matrix}[ Formula 4 ] & \\ Vd = - \frac{gm 1 \times gm 2 \times {V}_{OS}}{C \times {C}_{S} \times 2} \times 2 Δ T \times Δ T \times 2 & ( 8 )\end{matrix}$$

The OTA303 gradually applies negative feedback to the output of the amplifier circuit 301 through the analog discrete operation, where the periods 1T to 4T are set as one cycle, by using the input error component of the amplifier circuit 301 separated and extracted by the sample hold integrator circuit 400. More specifically, the OTA303 supplies a current proportional to the voltage Vd between the node 20 and the node 21 to the node 10 and the node 11. Here, if the current supplied to the node 10 and the node 11 is set as a current Id, it can be expressed by using the transconductance gm3 and the voltage Vd (Equation (8)) as Equation (9): Id=−gm1×gm2×gm3×Vos×2ΔT÷C×ΔT×2÷(Cs×2).

$$\begin{matrix}[ Formula 5 ] & \\ Id = - \frac{gm 1 \times gm 2 \times gm 3 \times {V}_{OS}}{C \times {C}_{S} \times 2} \times 2 Δ T \times Δ T \times 2 & ( 9 )\end{matrix}$$

The currents I11 and I12, expressed by Equations (1) and (2), are output from the amplifier circuit 301 to the node 10 and the node 11 throughout the periods 1T to 4T. According to Equations (1) and (2), both currents I11 and I12 include an error current “gm1×Vos” due to the offset voltage Vos. The OTA303 supplies the current Id, expressed by Equation (9), as a compensation current in a direction that cancels out the error current.

As described above, according to the amplifier of the embodiment, by configuring the amplifier circuit with an OTA and providing an OTA and a sample hold integrator circuit with a signal component separation function in the negative feedback path, it is possible to extract the input error component of the amplifier circuit from the current in which the signal component and the input error component of the amplifier circuit are mixed, and to gradually, as negative feedback, the extracted input error component through discrete analog operation. Through the negative feedback, the amplifier according to the embodiment can cancel out the input error component current of the first-stage amplifier circuit without arranging filters such as a low-pass filter (LPF) or a high-pass filter (HPF) on the signal transmission path used in the conventional chopper amplifiers. As a result, it is possible to obtain a signal component with the input error component removed.

According to the amplifier of the embodiment, it is possible to cancel the input error component current of the first-stage amplifier circuit without arranging filters on the signal transmission path used in conventional chopper amplifiers. Thus, the amplifier of the embodiment does not lower the accuracy of removing the error component included in the input signal, which is a drawback of not having filters in place. Moreover, since no filters are arranged, the drawbacks resulting from having filters do not arise. In other words, the amplifier according to the embodiment can obtain a signal component with the input error component removed without generating signal distortion that occurs when the signal passes through filters, and without the influence of the distortion.

The invention is not limited to the embodiments described above, and at the implementation stage, it can be practiced in various forms other than the examples described above. Within the scope of the invention, various omissions, additions, substitutions, or modifications can be made. For example, the timing for the level transition of the control signals φ1, φ2, φ3, φ4, φ1A, φ1B, φ2A, and φ2B in the amplifier 100 is not limited to the timing exemplified in FIG. 4. In the amplifier 100, it is possible to select any timing from amongst the timings of being caused to operate to be able to supply, as a compensation current, the current Id represented in Equation (9) above in a direction that cancels the error current. In addition, the polarities of the input terminals and the output terminals of the amplifier circuit 301, the OTA302, the OTA303, and the amplifier circuit 304 may be designed as appropriate. The embodiments and the modifications are included in the scope and essence of the invention, as well as within the scope of the invention described in the claims and its equivalents.

What is claimed is:

1. An amplifier, comprising:
a first signal polarity inversion circuit, outputting, in a non-inverted or inverted polarity, an input signal input from an input terminal;
a first voltage-current conversion circuit, connected with the first signal polarity inversion circuit, generating an output current based on an output voltage of the first signal polarity inversion circuit, and outputting the output current from a first output terminal and a second output terminal;
a second signal polarity inversion circuit, having a first input terminal and a second input terminal respectively connected with the first output terminal and the second output terminal of the first voltage-current conversion circuit, and outputting, in a non-inverted or inverted polarity, the current output from the first voltage-current conversion circuit;
a load capacitor, connected with the second signal polarity inversion circuit, and obtaining a voltage based on the current output from the second signal polarity inversion circuit; and
a compensation circuit, wherein a first terminal of the load capacitor and a first node are connected, the first node being a connection point between the first output terminal of the first voltage-current conversion circuit and a first input terminal of the second signal polarity inversion circuit, a second terminal of the load capacitor and a second node are connected, the second node being a connection point between the second output terminal of the first voltage-current conversion circuit and a second input terminal of the second signal polarity inversion circuit, a voltage of the load capacitor comprises an input error component of the first voltage-current conversion circuit, and an input error component current corresponding to the input error component is extracted from the voltage between the terminals of the load capacitor, the input error component current that is extracted is negatively fed back to the first node and the second node.

2. The amplifier as claimed in claim 1, wherein the amplifier is configured to operate cyclically, and
the compensation circuit comprises:
a second voltage-current conversion circuit, connected with the load capacitor and generating a current based on the voltage between the terminals of the load capacitor;
a sample hold integrator circuit, possessing an integration property of having a capacitor and being connected with the second voltage-current conversion circuit, extracting the input error component current by removing, from a current in which a signal component of an input signal comprised in the current output from the second voltage-current conversion circuit and the input error component are mixed, the signal component to output as an output voltage while storing, as a charging voltage of the capacitor, a magnitude of the input error component in an n^{th} cycle, n being an natural number, and starting sampling of the input error component in an (n+1)^{th} cycle from the charging voltage of the n^{th} cycle; and
a third voltage-current conversion circuit, connected with the sample hold integrator circuit, converting a voltage between a first output terminal and a second output terminal of the sample hold integrator circuit into the input error component current to be supplied to the first node and the second node.

3. The amplifier as claimed in claim 2, wherein the sample hold integrator circuit comprises a capacitor pair connectible in parallel as the capacitor, and
the capacitor pair has a first capacitor and a second capacitor, wherein the first capacitor samples a charge based on a current output from the first voltage-current conversion circuit in a case where the second signal polarity inversion circuit outputs a signal in a non-inverted relationship, and the second capacitor samples a charge based on a current output from the first voltage-current conversion circuit in a case where the second signal polarity inversion circuit outputs a signal in an inverted relationship.
